(19) United States
(12) Patent Application Publication
(10) Pub. No.: US 2016/0205802 A1
(43) Pub. Date: Jul. 14, 2016

(54) SERVER INSERT FOR A SERVER RACK

(71) Applicant: FUJITSU TECHNOLOGY SOLUTIONS INTELLECTUAL PROPERTY GMBH, München (DE)

(72) Inventors: Friedrich Köhler, Augsburg (DE); Lorenz Schelshorn, Augsburg (DE)

(21) Appl. No.: 14/913,401

(22) PCT Filed: Jul. 23, 2014
(86) PCT No.: PCT/EP2014/065852

§ 371 Date: Feb. 22, 2016

(30) Foreign Application Priority Data
Aug. 23, 2013 (DE) 10 2013 109 164.4

(51) Int. Cl. H05K 7/14

(52) U.S. Cl. CPC H05K 7/1487; H05K 7/1439

(57) ABSTRACT

A server insert for a server rack includes an insert housing with a housing base; an installation cage device disposed within the insert housing on the housing base and extending substantially across an entire width of the insert housing; and a backplane or midplane printed circuit board secured in a force-fitting manner on the installation cage device substantially perpendicular to the housing base and disposed on the housing base in a form-fitting manner such that the printed circuit board mechanically reinforces the installation cage device and reinforcing of the insert housing is effected.

### TECHNICAL FIELD

This disclosure relates to a server insert for a server rack having an insert housing with a housing base and an installation cage device.

### BACKGROUND

A server rack generally comprises a multiplicity of servers which in the form of insert modules are inserted into one or a plurality of server frames of the server rack, and thus may also be referred to as server inserts. The server inserts typically comprise one or a plurality of processors and memory chips and insert components, for example, hard disk memory drives. The insert components are typically accessible from a front side of the server insert or of the server rack, respectively, and insertable into one or a plurality of installation cages within a server insert.

It could nonetheless be helpful to provide a server insert for a server rack, which is distinguished by simple construction and high mechanical stability.

### SUMMARY

We provide a server insert for a server rack including an insert housing with a housing base; an installation cage device disposed within the insert housing on the housing base and extending substantially across an entire width of the insert housing; and a backplane or midplane printed circuit board secured in a force-fitting manner on the installation cage device substantially perpendicular to the housing base and disposed on the housing base in a form-fitting manner such that the printed circuit board mechanically reinforces the installation cage device and reinforcing of the insert housing is effected.

### BRIEF DESCRIPTION OF THE DRAWINGS

FIG. 1 shows a perspective illustration of a server insert.

FIG. 2 shows a plan view of a server insert from the rear.

### LIST OF REFERENCE SIGNS

D Pin
DB Deflection
EG Insert housing
EK Installation cage
ER Insertion direction
GB Housing base
GWL Left housing wall
GWR Right housing wall
LP Printed circuit board
N Groove
OE Opening
RS Rear side
SE Server insert
SV Screw connection
US Lower side
VS Front side

### DETAILED DESCRIPTION

Our server insert for a server rack has an insert housing with a housing base. The server insert furthermore has an installation cage device disposed within the insert housing on the housing base and extends substantially across an entire width of the insert housing. The server insert furthermore has a printed circuit board, in particular a backplane or midplane, secured in a force-fitting manner on the installation cage device to be substantially perpendicular to the housing base and disposed on the housing base in a form-fitting manner such that the printed circuit board mechanically reinforces the installation cage device and reinforcing of the insert housing is effected.

The housing base can also be called a housing bottom or housing bottom wall. The installation cage device can also be called a mounting cage device. Force-fitting manner means, for example, a force-locking, force-fit or friction-locking connection. Form-fitting manner means, for example, a positive-fit connection or form-fit connection.

Installation cage devices typically receive a multiplicity of insert components such as hard disk drives, for example, on account of which a heavy weight acts on the installation cage device and thus on the housing base of the insert housing. For a design of the insert housing and of the installation cage device which is as space-saving as possible to be achieved, comparatively thin sheet-metal panels are used as housing components such that deflection of the installation cage device and thus of the housing base may arise on account of the weight.

On account of the printed circuit board being secured in a force-fitting manner on the installation cage device in the server insert, the installation cage device is inherently reinforced. In particular, the printed circuit board is secured in a force-fitting manner on the installation cage device in a plurality of lateral regions of the latter. The installation cage device thus forms a reinforced unit across an entire width of the insert housing on account of which deflection of the housing base is substantially prevented. The printed circuit board is typically made from a stable printed circuit board material such that the printed circuit board may absorb the bending and/or weight forces being created.

On account of the printed circuit board being attached to the installation cage device in a force-fitting manner, an additional support brace, for example, from a metallic material, to reinforce the insert housing or the installation cage device, respectively, may be dispensed with. Thus, weight and production costs may be reduced while maintaining mechanical stability. In addition, improved handling during assembly of insert components or other components of the server insert is provided since there is more available installation space within the insert housing of the server insert.

Server inserts typically require the printed circuit board for so-called “hot plugging” in which the insert components may be exchanged or replaced during operation. For example, hard disk drives may be inserted into the installation cage device and contact thereof with the printed circuit board may be established by a direct plug connection. It is necessary that the printed circuit board absorbs the forces being created during insertion and transfers the forces to the insert housing such that the printed circuit board is not deflected in the insertion direction of the insert component and not damaged. To this end, the printed circuit board is additionally disposed in a form-fitting manner on the housing base such that the former is protected against deflection in the insertion direction.

The installation cage device may have two or a plurality of installation cages, in particular hard disk cages, wherein the printed circuit board is secured in a force-fitting manner on the installation cage device such that the printed circuit board mechanically connects the installation cages and reinforces the installation cages. An installation cage can also be called a mounting cage. On account thereof, the installation cages are mutually reinforced and form a unit. This prevents deflection of the installation cages or of the unit per se, respectively, and thus deflection of the housing base.

The printed circuit board may be secured in a force-fitting manner on the housing base. On account thereof, the printed circuit board is also secured in a mechanically reliable manner on the housing base. Moreover, higher mechanical stability is guaranteed, in particular in relation to deflection of the printed circuit board in the insertion direction of the insert components.

The printed circuit board may be disposed in a form-fitting manner on the installation cage device. The printed circuit board is thus not only secured in a force-fitting manner, but also in a form-fitting manner on the installation cage device on account of which additional reinforcement may be achieved. Additionally, assembly of the printed circuit board on the installation cage device is improved or simplified since force-fitting and form-fitting assembly is less complex than purely force-fitting assembly, for example, by screw connections. In particular, part of the screw connections may be dispensed with on account of the additional form-fitting feature.

The housing base may have at least one groove and/or at least one gate guide to receive in a form-fitting manner a lower side of the printed circuit board. A gate guide can also be called a slotted guide system, a guide mechanism or guide rail. On account thereof, a simple possibility for the form-fitting feature between the printed circuit board and the housing base is provided. Designs of this type of a form-fitting feature are typically of simple geometry and are thus easy to manufacture and assemble.

The printed circuit board may be disposed in a form-fitting manner on two mutually opposite housing walls of the insert housing, which are disposed perpendicularly to the housing base. On account thereof, mechanical securing of the printed circuit board in the insert housing is further facilitated.

The housing walls may have at least one groove and/or at least one gate guide to receive in a form-fitting manner the printed circuit board. Designs of this type of a form-fitting feature are typically of simple geometry and therefore easy to manufacture and assemble.

The installation cage device may have one or a plurality of pins, in particular guide pins and/or screw pins configured to engage in a form-fitting manner in one or a plurality of corresponding openings of the printed circuit board. Screw pins or guide pins guarantee simple possibilities as to how the form-fitting feature between the printed circuit board and the installation cage device may be implemented. The pins can also be called a mandrel, which means, for example, that the pins are tapered at one end. To this end, the screw pins or guide pins are merely screwed or plugged into the installation cage device such that the printed circuit board in a form-fitting manner may be push-fitted or plugged onto the screw pins or guide pins.

Further examples are disclosed in the following detailed description.

Our server inserts will be described in more detail hereunder by the examples with reference to the appended figures.

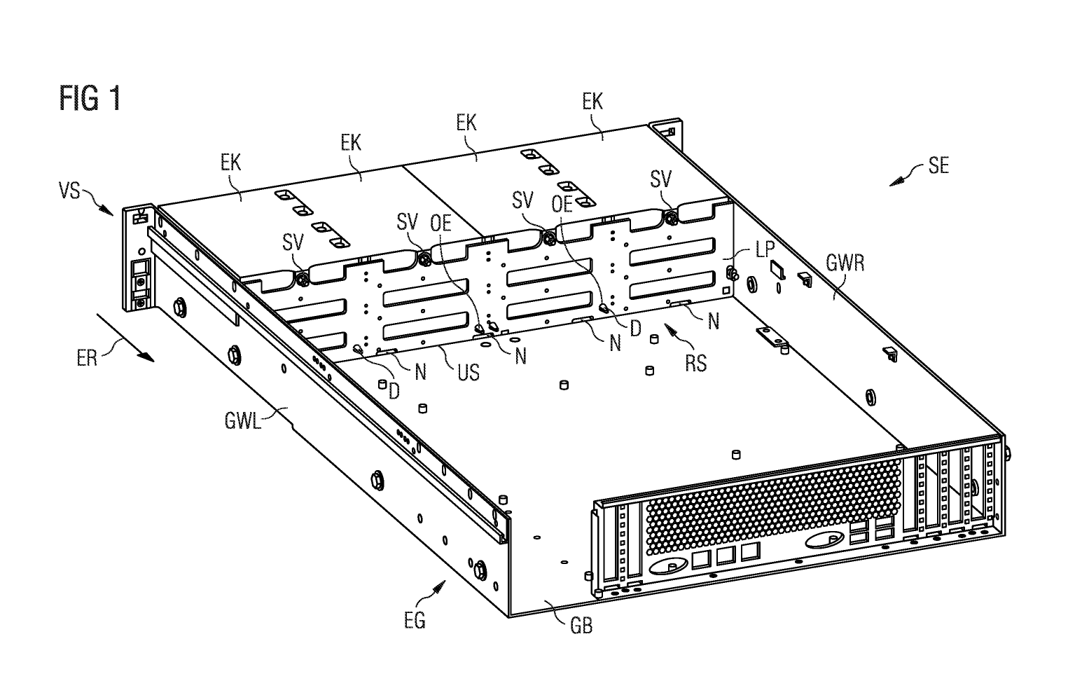

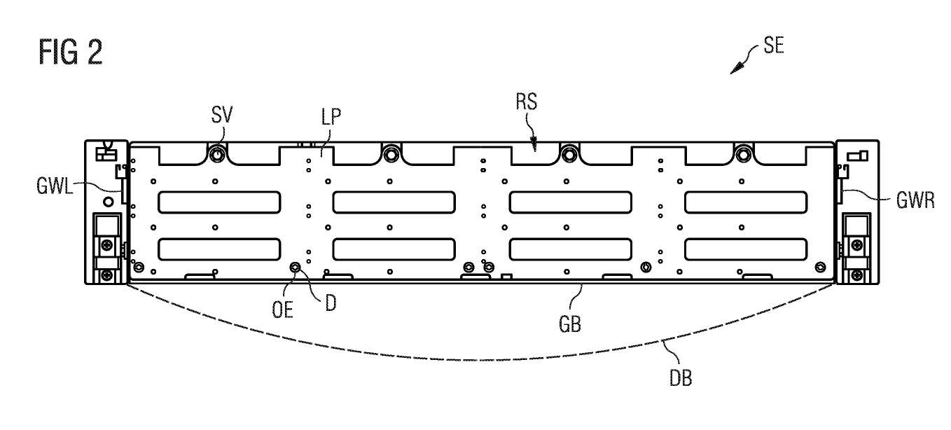

FIGS. 1 and 2 show a server insert SE for a server rack. The server insert SE has an insert housing EG, which has a housing base GB, a left housing wall GWL, and a right housing wall GWR. In relation to the housing base GB, the two housing walls GWR and GWL are bent at 90° in the normal direction.

A plurality of installation cages EK are disposed in the interior of the insert housing EG, the housing cover of the latter not being shown for reasons of clarity. The installation cages EK may also be referred to as an installation cage device. The installation cages EK are located in the region of a front side VS of the server insert SE. The installation cages EK in the example contain hard disk drives (not illustrated). Alternatively, other insert components may also be disposed or assembled within the installation cages EK. The hard disk drives or insert components, respectively, are accessible from the front side VS of the server insert SE, and may be introduced or plugged into an installation cage EK in an insertion direction ER, respectively. A printed circuit board LP is additionally disposed in the interior of the server insert SE. Further components necessary to operate a server insert SE are not illustrated for reasons of clarity.

The printed circuit board LP is directly secured and in a force-fitting manner on rear sides RS of the installation cages EK or of the installation cage device, respectively. The printed circuit board LP is screwed by way of screw connections SV to each of the installation cages EK. Alternatively, other mechanical connection techniques are also possible. The printed circuit board is screwed to the installation cages EK in lateral regions of the latter. In particular, the printed circuit board is screwed to the installation cages EK in upper lateral regions of the installation cages EK facing away from the housing base GB. The printed circuit board LP connects to the installation cages EK or with the installation cage device, respectively, across an entire width of the insert housing EG.

Additionally, the printed circuit board LP is disposed in a form-fitting manner on each of the installation cages EK. To this end, a plurality of openings OE through which pins D are guided are incorporated into the printed circuit board LP. The pins D are secured in a mechanically fixed manner on the installation cages EK, for example, screwed to the installation cages EK. The pins D are disposed on lateral regions of the installation cages EK or installation cage device, respectively, in particular on lower lateral regions facing the housing base GB. The pins D are guide pins and screw pins. Alternatively, other design elements such as metal lugs, for example, that engage openings of the printed circuit board LP, are possible.

The printed circuit board LP mechanically connects the installation cages EK and thus reinforces the installation cages EK in the longitudinal extent of the printed circuit board LP. This means that the installation cages EK are reinforced in relation to deflection DB in the normal direction of the housing base GB, the deflection DB from left to right or from the left housing wall GWL to the right housing wall GWR, respectively, being schematically shown in the two-dimensional view of FIG. 2. The reinforcement is necessary so that deflection DB of the housing base GB on account of a weight of the hard disk drives disposed in the interior of the installation cages EK is prevented. The installation cages EK are typically made from thin sheet-metal panels which may be easily elastically deformed under the weight of the hard disk drives. On account thereof, deflection DB which is shown in a schematic manner would arise, causing problems in particular when the server insert SE is inserted into a server rack.

A plurality of server inserts are typically disposed to be tightly packed on top of one another in a server rack such that during insertion of a server insert SE server inserts lying therebelow would be damaged on account of deflection DB. The reason therefor lies in that, on account of a deflected housing base GB, the entire server insert SE would assume a height greater than a maximum height, and the housing base GB during insertion would touch a server insert SE lying therebelow. Apart from damage to the server lying therebelow, inserting per se would meet with more resistance.

Deflection DB is prevented by the printed circuit board LP in the example according to FIGS. 1 and 2 such that the weight forces are compensated for by way of the printed circuit board LP. An additional component such as a support brace from metal, for example, which is fitted in the insert housing EG between the left housing wall and the right housing wall GWL and GWR, respectively, may be dispensed with.

It should be pointed out that this form-fitting feature is alternatively not mandatorily required if a connection sufficiently force-fitting is established between the printed circuit board LP and the installation cages EK. Attention must merely be paid to the fact that the installation cage device is mechanically reinforced across an entire width of the insert housing EG, or that each installation cage EK mechanically connects by way of the printed circuit board LP, respectively, by a form-fitting feature and/or a force-fitting feature.

For direct contact to be able to be established between the hard disk drives and the printed circuit board LP, for example, so-called hot plugging, the printed circuit board LP is additionally disposed in a form-fitting manner on the housing base GB. To this end, grooves N or other types of guides such as gate guides that receive in a form-fitting manner a lower side US of the printed circuit board are disposed on the housing base. The printed circuit board LP per se is thus protected against deflection in the insertion direction ER of the insert components.

Alternatively (not shown), the printed circuit board LP may also be mechanically secured in a force-fitting manner on the housing base GB, for example, by screw connections. This further facilitates mechanical and reliable securing of the printed circuit board LP within the insert housing EG.

Further alternatively (not shown), the printed circuit board LP is disposed on the left housing wall GWL and/or the right housing wall GWL of the insert housing EG. This may be implemented by additional grooves or gate guides. An arrangement of this type additionally supports the printed circuit board LP in terms of force absorption such that the forces in the insertion direction ER, which have been absorbed by the printed circuit board LP, may be dissipated via the insert housing EG.

1.-8. (canceled)

9. A server insert for a server rack comprising:
an insert housing with a housing base;
an installation cage device disposed within the insert housing on the housing base and extending substantially across an entire width of the insert housing; and
a backplane or midplane printed circuit board secured in a force-fitting manner on the installation cage device substantially perpendicular to the housing base and disposed on the housing base in a form-fitting manner such that the printed circuit board mechanically reinforces the installation cage device and reinforcing of the insert housing is effected.

10. The server insert according to claim 9, wherein the installation cage device has two or a plurality of installation cages, and the printed circuit board is secured in a force-fitting manner on the installation cage device such that the printed circuit board mechanically connects the installation cages and reinforces the installation cages.

11. The server insert according to claim 9, wherein the printed circuit board is secured in a force-fitting manner on the housing base.

12. The server insert according to claim 9, wherein the printed circuit board is disposed in a form-fitting manner on the installation cage device.

13. The server insert according to claim 9, wherein the housing base has at least one groove and/or at least one gate guide that receives in a form-fitting manner a lower side of the printed circuit board.

14. The server insert according to claim 9, wherein the printed circuit board is disposed in a form-fitting manner on two mutually opposite housing walls of the insert housing disposed perpendicular to the housing base.

15. The server insert according to claim 14, wherein the housing walls each have at least one groove and/or at least one gate guide that receive in a form-fitting manner the printed circuit board.

16. The server insert according to claim 9, wherein the installation cage device has one or a plurality of guide pins and/or screw pins configured to engage in a form-fitting manner in one or a plurality of corresponding openings of the printed circuit board.

17. The server insert according to claim 10, wherein the printed circuit board is secured in a force-fitting manner on the housing base.
